(19) United States
(12) Patent Application Publication
(10) Pub. No.: US 2026/0293084 A1
(43) Pub. Date: Sep. 24, 2026

(54) METHOD OF MANUFACTURING SEMICONDUCTOR STRUCTURE AND SEMICONDUCTOR STRUCTURE THEREOF

(71) Applicant: NANYA TECHNOLOGY CORPORATION, NEW TAIPEI CITY (TW)

(72) Inventor: JUNG-YU WU, NEW TAIPEI CITY (TW)

(21) Appl. No.: 19/176,424

(22) Filed: Apr. 11, 2025

Related U.S. Application Data
(63) Continuation of application No. 19/087,836, filed on Mar. 24, 2025.

(51) Int. Cl. H10B 12/00; H10P 50/00

(52) U.S. Cl. CPC H10B 12/01; H10P 50/71; H10P 50/73

(57) ABSTRACT

A method of manufacturing a semiconductor structure includes sequentially forming a bit line stack on a substrate, a nitride-containing layer on the bit line stack, a hard mask layer on the nitride-containing layer, and a carbon-containing layer on the hard mask layer, wherein the hard mask layer includes metal oxide and a rate of etching the hard mask layer by an etchant is greater than a rate of etching the nitride-containing layer by the etchant; patterning the carbon-containing layer to expose a portion of the hard mask layer; removing the portion of the hard mask layer to form a hard mask, thereby exposing a portion of the nitride-containing layer; removing the carbon-containing layer after the formation of the hard mask; and using the hard mask to pattern the nitride-containing layer and the bit line stack, thereby forming a bit line and a nitride-containing element.

### CROSS-REFERENCE TO RELATED APPLICATION

This application is a continuation application of U.S. Non-Provisional Application No. 19/087,836 filed March 24, 2025, which is incorporated herein by reference in its entirety.

### TECHNICAL FIELD

The present disclosure relates to a method of manufacturing a semiconductor structure, and a semiconductor structure manufactured by the method. Particularly, the present disclosure relates to a method of manufacturing a semiconductor structure including forming a hard mask layer between a nitride-containing layer and a carbon-containing layer, and the semiconductor structure formed using the hard mask layer.

### DISCUSSION OF THE BACKGROUND

Semiconductor devices are used in a variety of electronic applications, such as personal computers, cellular telephones, digital cameras, and other electronic equipment, and capacitors are used in a wide variety of semiconductor circuits. DRAM memory circuits are manufactured by replicating millions of identical circuit elements, known as DRAM cells, on a single semiconductor wafer. A DRAM cell is an addressable location that can store one bit (binary digit) of data. In its most common form, a DRAM cell consists of two circuit components, a storage capacitor and an access field-effect transistor. In recent years, as sizes of DRAM technology nodes have continued to scale down, conductive structures in DRAM devices are becoming closer together and smaller in size. As a result, contact resistances of the devices are increasing, which in turn decrease a device's on-current and operation speed.

In order to form integrated circuits on wafers, lithography processes are used. A typical lithography process involves applying a photoresist and then defining patterns on the photoresist. The patterns on the patterned photoresist are defined in a lithography mask layer, and are defined either by transparent portions or by opaque portions in the lithography mask layer. The patterns on the patterned photoresist are then transferred to underlying layers through an etching step, wherein the patterned photoresist is used as an etching mask layer. After the etching step, the patterned photoresist is removed.

As demand for smaller electronic devices including integrated circuits increases, high aspect ratio stacking of layers used in photo patterning techniques can lead to poor wiggling resistance during pattern transfer to the underlying layers.

Line wiggling occurs when a pattern defined by a mask layer having a high aspect ratio (i.e., a high height-to-width ratio) is transferred onto a patterning layer there beneath. Etching of the patterning layer through the high-aspect-ratio mask layer causes the patterning layer to have excessive wiggling. With excessive wiggling in the patterning layer, when an underlying target layer is patterned to form openings for metal lines, the openings and the resulting metal lines will also have excessive wiggle. Excessive wiggle can cause shorts, bridging, and unplanned breaks in the subsequently-formed metal lines.

This Discussion of the Background section is provided for background information only. The statements in this Discussion of the Background are not an admission that the subject matter disclosed in this Discussion of the Background section constitute prior art to the present disclosure, and no part of this Discussion of the Background section may be used as an admission that any part of this application, including this Discussion of the Background section, constitutes prior art to the present disclosure.

### SUMMARY

One aspect of the present disclosure provides a method of manufacturing a semiconductor structure. The method includes providing a substrate having an active region, wherein the active region includes an isolation structure and a contact adjacent to the isolation structure; forming a bit line stack on the substrate; forming a nitride-containing layer on the bit line stack; and forming a hard mask layer on the nitride-containing layer, wherein the hard mask layer includes metal oxide and a rate of etching the hard mask layer by an etchant is greater than a rate of etching the nitride-containing layer by the etchant. The method further includes forming a carbon-containing layer on the hard mask layer; patterning the carbon-containing layer to expose a portion of the hard mask layer; removing the portion of the hard mask layer to form a hard mask having an opening, thereby exposing a portion of the nitride-containing layer; removing the carbon-containing layer after the formation of the hard mask; and using the hard mask to pattern the nitride-containing layer and the bit line stack, thereby forming a bit line on the contact and a nitride-containing element on the bit line.

Another aspect of the present disclosure provides a method of manufacturing a semiconductor structure. The method includes providing a substrate having an active region, wherein the active region includes a contact; forming a barrier layer on the substrate; forming a conductive layer on the barrier layer; forming a nitride-containing layer on the conductive layer; forming a hard mask layer on the nitride-containing layer, wherein a rate of etching the hard mask layer by an etchant is greater than a rate of etching the nitride-containing layer by the etchant; and forming a carbon-containing layer on the hard mask layer. The method further includes patterning the carbon-containing layer and the hard mask layer to form a hard mask having an opening, thereby exposing the nitride-containing layer; removing the carbon-containing layer after the formation of the hard mask; and using the hard mask to pattern the nitride-containing layer, the conductive layer and the barrier layer, thereby forming a bit line and a nitride-containing element on the bit line, wherein the nitride-containing layer is patterned after the removal of the carbon-containing layer.

Another aspect of the present disclosure provides a semiconductor structure. The semiconductor structure includes a substrate comprising an active area; a contact disposed in the active area; and a bit line electrically connected to the contact, wherein the bit line includes a first portion and second portion disposed over the first portion, wherein a first width of the first portion is substantially equal to a second width of the second portion.

Due to the removal of the carbon-containing layer before the formation of the bit line, the bit line formed by the method of the present disclosure is free of residue from the carbon-containing layer disposed thereon. Moreover, the present disclosure reduces a height-to-width aspect ratio of the carbon-containing layer used to pattern a patterning layer, wherein the patterning layer comprises the hard mask layer including metal oxide. Reducing the height-to-width aspect ratio allows the hard mask to be formed with openings having less wiggle. Subsequently, when the patterning layer is used to pattern a target layer, corresponding openings in the target layer, which includes the nitride-containing layer and the bit line stack, are likewise straighter and result in straighter bit lines, which are less prone to shorts, bridging, and unplanned breaks.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

A more complete understanding of the present disclosure may be derived by referring to the detailed description and claims. The disclosure should also be understood to be coupled to the figures’ reference numbers, which refer to similar elements throughout the description.

FIG. 1 is a flow diagram illustrating a method of manufacturing a semiconductor structure in accordance with some embodiments of the present disclosure.

FIG. 2 is a flow diagram illustrating a method of manufacturing a semiconductor structure in accordance with some embodiments of the present disclosure.

FIGS. 3 to 9 are cross-sectional views of intermediate stages in formation of a semiconductor structure in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another element, component, region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limiting to the present inventive concept. As used herein, the singular forms “a,” “an” and “the” are intended to include the plural forms as well, unless the context clearly indicates otherwise. It shall be understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

In the present disclosure, a semiconductor structure and a method of manufacturing a semiconductor structure are provided. A semiconductor device includes a bit line, and the method of manufacturing the semiconductor structure includes forming the bit line at a portion of a memory array. In order to form the bit line, the method includes forming a hard mask layer between a nitride-containing layer and a carbon-containing layer, and transferring a pattern of the carbon-containing layer to the hard mask layer. Compared to methods that do not use a hard mask layer, a thickness of the carbon-containing layer of the present disclosure is greatly reduced, and the thus-formed bit line is likewise straighter, making it less prone to shorts, bridging, and unplanned breaks.

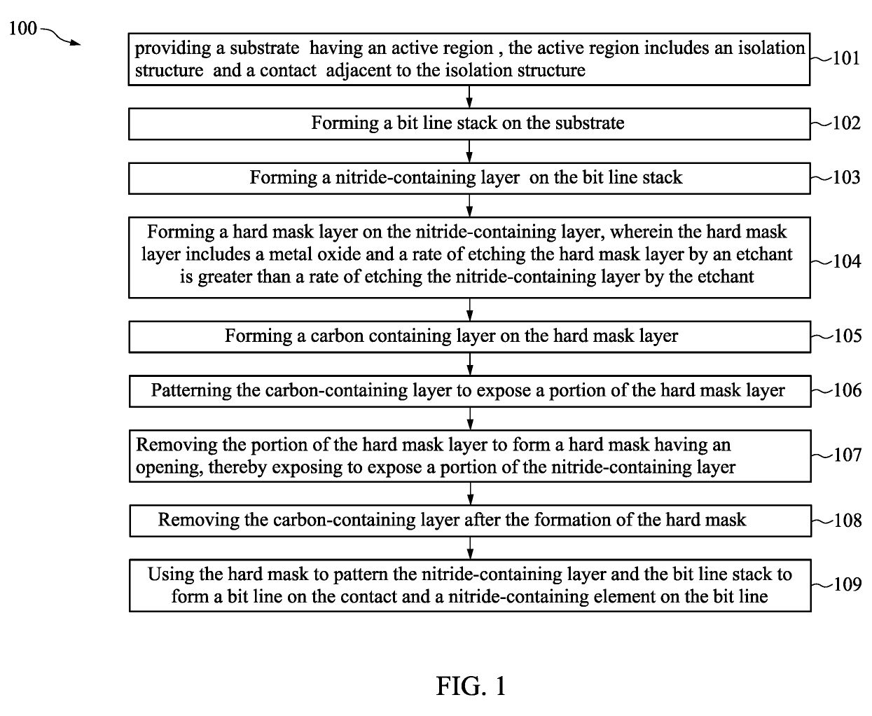

According to some embodiments of the present disclosure, a method for manufacturing a semiconductor structure is disclosed. FIG. 1 is a flowchart of the method 100 in accordance with some embodiments. The method 100 includes a number of operations (101 to 109), and descriptions and illustrations are not deemed as a limitation to a sequence of the operations. Additional steps can be provided before, during, and after the operations shown in FIG. 1, and some of the operations described below can be replaced or eliminated in other embodiments of the method 100. An order of the operations may be interchangeable.

Referring to FIG. 1, the method 100 begins with operation 101. Operation 101 includes providing a substrate having an active region, wherein the active region includes an isolation structure and a contact adjacent to the isolation structure. The method 100 continues with operations 102 to 109.

Operation 102 includes forming a bit line stack on the substrate. Operation 103 includes forming a nitride-containing layer on the bit line stack. Operation 104 includes forming a hard mask layer on the nitride-containing layer, wherein the hard mask layer includes metal oxide and a rate of etching the hard mask layer by an etchant is greater than a rate of etching the nitride-containing layer by the etchant. Operation 105 includes forming a carbon-containing layer on the hard mask layer. Operation 106 includes patterning the carbon-containing layer to expose a portion of the hard mask layer. Operation 107 includes removing the portion of the hard mask layer to form a hard mask having an opening that exposes a portion of the nitride-containing layer. Operation 108 includes removing the carbon-containing layer after the formation of the hard mask. Operation 109 includes using the hard mask to pattern the nitride-containing layer and the bit line stack to form a bit line on the contact and a nitride-containing element on the bit line.

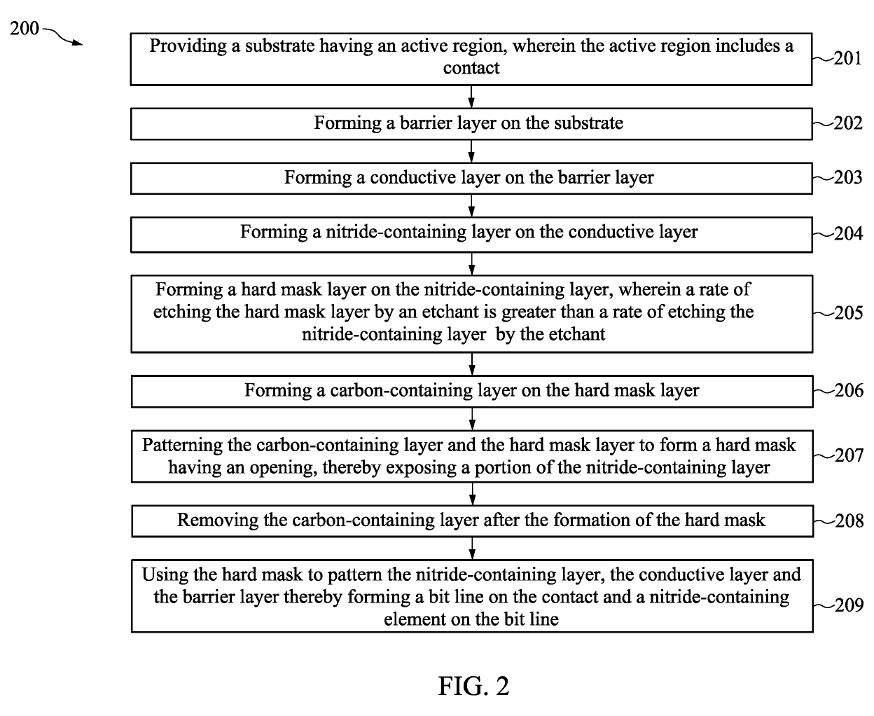

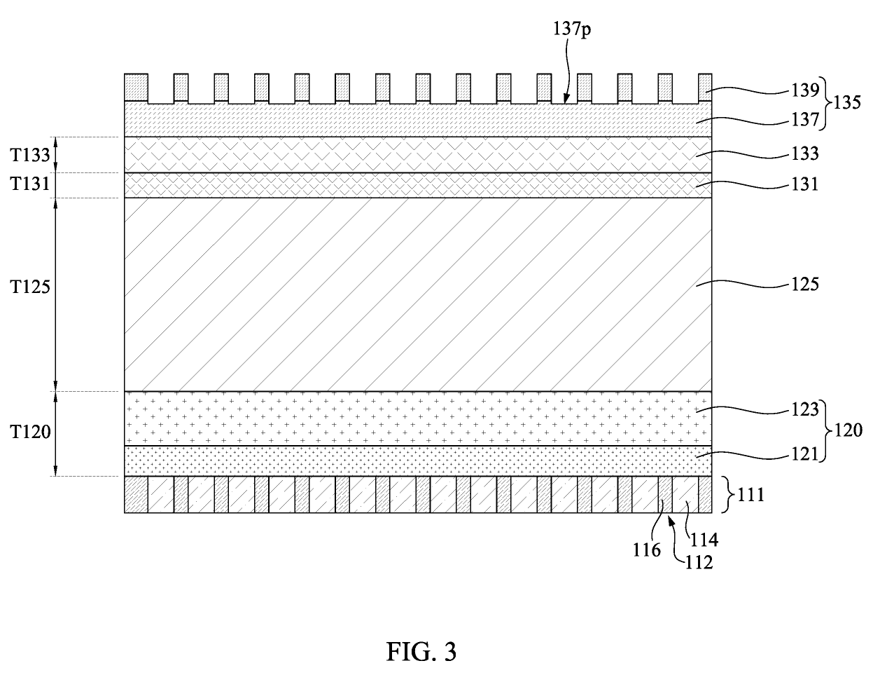

According to some embodiments of the present disclosure, a method for manufacturing a semiconductor structure is disclosed. FIG. 2 is a flowchart of the method 200 in accordance with some embodiments. The method 200 includes a number of operations (201 to 209), and descriptions and illustrations are not deemed as a limitation to a sequence of the operations. Additional steps can be provided before, during, and after the operations shown in FIG. 2, and some of the operations described below can be replaced or eliminated in other embodiments of the method 200. An order of the operations may be interchangeable. FIGS. 3 to 9 are schematic cross-sectional views of one or more operations of the method 200 for manufacturing a semiconductor structure in accordance with some embodiments of the present disclosure.

Referring to FIG. 2, the method 200 begins with operation 201. Operation 201 includes providing a substrate having an active region, wherein the active region includes a contact. In some embodiments, operation 201 of the method 200 is similar to operation 101 of the method 100.

In some embodiments, referring to FIG. 3, a substrate 111 having an active region 112 is provided. In some embodiments, the substrate 111 is a semiconductor layer. In some embodiments, the substrate 111 includes semiconductor material. In some embodiments, the substrate 111 is a silicon substrate. In some embodiments, the active region 112 includes silicon. In some embodiments, the active region 112 can function as a channel for electrical connection. In some embodiments, the active region 112 comprises p-type implanted dopants or n-type implanted dopants. In some embodiments, the substrate 111 is processed to form a plurality of active regions 112. Several steps are typically involved, such as forming a thin oxide layer of silicon dioxide (SiO₂) on a surface of the substrate 111. This can be achieved through thermal oxidation, where the substrate 111 is exposed to an oxygen-rich environment at high temperatures, or by any acceptable deposition process, such as spin coating, chemical vapor deposition (CVD), atomic layer deposition (ALD), physical vapor deposition (PVD), laminating, the like, or a combination thereof.

In some embodiments, a layer of photosensitive material, known as photoresist, is applied onto the oxide layer. The photoresist is then exposed to ultraviolet (UV) light through an etching mask containing a desired pattern. This step transfers the pattern onto the photoresist. The exposed photoresist is developed using a suitable developer solution. This selectively removes either the exposed (positive photoresist) or unexposed (negative photoresist) regions of the photoresist, leaving behind the desired pattern. An etching process, such as plasma etching, dry etching or wet etching, is used to selectively remove the exposed oxide layer where the active region will be formed. The patterned photoresist acts as a mask, protecting the regions where the oxide is desired. In some embodiments, ion implantation is performed to introduce p-type or n-type dopant atoms into exposed regions of the substrate 111 where active devices will subsequently be formed. The dopant atoms modify electrical properties of the substrate 111, creating active regions 112 with desired conductivity characteristics. The implanted dopant atoms are activated and crystal lattice damage caused by the implantation process is repaired through an annealing process. This step typically involves subjecting the substrate 111 to high temperatures for a specific duration.

In some embodiments, the substrate 111 includes an isolation structure 114 and a contact 116 adjacent to the isolation structure 114 and within the active region 112. In some embodiments, the active regions 112 may include silicon. The isolation structure 114 may include oxide, such as silicon oxide or another suitable material. The isolation structure 114 may be a shallow trench isolation (STI) structure. In some embodiments, the active region 112 includes a plurality of isolation structures 114 and a plurality of contacts 116, wherein each of the contacts 116 is adjacent to a corresponding isolation structure 114.

In some embodiments, a plurality of isolation structures 114 are also formed between adjacent active regions 112 to achieve electrical isolation. In some embodiments, the plurality of active regions 112 can be separated by the corresponding isolation structures 114. In some embodiments, the isolation structures 114 are embedded in the substrate 111. In some embodiments, the isolation structures 114 may include, for example, silicon oxide (SiO₂), silicon nitride (Si₃N₄), silicon oxynitride (N₂OSi₂), silicon nitride oxide (N₂OSi₂), or other suitable materials.

The isolation structures 114 can be formed by a series of steps such as trench formation, etching, liner deposition, trench filling, and planarization. In some embodiments, a trench pattern is created on a wafer surface using lithography techniques. The trench pattern defines a location and dimensions of isolation trenches. A masking material, such as photoresist, is applied over the wafer surface, and the wafer surface is then exposed to ultraviolet (UV) light through a mask, followed by development to form a photoresist pattern. Exposed areas of the wafer surface are then etched away using a dry or wet etching process, forming the isolation trenches.

In some embodiments, a thin layer of oxide, called a liner, is deposited on sidewalls and a bottom of the isolation trenches. The liner is usually comprised of silicon dioxide (SiO₂) or another suitable dielectric material. The liner helps improve electrical isolation and prevents contaminants from diffusing into the active regions 112. The isolation trenches are filled with a dielectric material, such as CVD oxide or a combination of oxide and other materials like silicon nitride (Si₃N₄). Excess fill material is typically removed using a chemical mechanical planarization (CMP) process, which levels the wafer surface. The wafer surface is thus planarized to ensure that the wafer surface is uniform and flat, eliminating any irregularities or topographic variations caused by the trench filling process.

In some embodiments, the plurality of contacts 116 are formed on the active regions 112. In some embodiments, each of the active regions 112 includes a corresponding one of the contacts 116. In some embodiments, the plurality of contacts 116 and the plurality of isolation structures 114 are alternately disposed in the substrate 111.

In some embodiments, in a semiconductor memory array, the plurality of contacts 116, also known as bit line contacts or bit line contact plugs, are crucial components that establish an electrical connection between bit lines and memory cells or transistors. Such configuration allows for transmission of signals and data between the memory cells and the bit lines in the memory array. In some embodiments, the contacts 116 are configured to form the bit lines (not shown) thereon. The contacts 116 may include a conductive material, such as W, Cu, Ru, Ir, Ni, Os, Rh, Al, Mo, Co, an alloy thereof, a combination thereof, or any metallic material with suitable resistance and gap-fill capability.

In some embodiments, the contacts 116 can be formed by a series of steps such as dielectric layer deposition, photolithography, etching, conductive material deposition or planarization. In some embodiments, a dielectric layer may be deposited over a memory array region. The dielectric layer acts as an insulating material, providing electrical isolation between different components of the memory array. A layer of photosensitive material, known as photoresist, is applied onto the dielectric layer. Photolithography techniques are then used to define locations where the contacts 116 are to be formed. The photolithography techniques include exposing the photoresist to UV light through an etching mask containing desired contact patterns. An etching process is used to remove the dielectric layer in areas not protected by the photoresist. The etching process creates openings or cavities in the locations where the contacts 116 are to be formed.

In some embodiments, a conductive material, such as a metal or a metal alloy, is deposited into the openings or cavities to form the plurality of contacts 116. In some embodiments, the conductive material is polysilicon, and the plurality of contacts 116 includes polysilicon. In some embodiments, a planarization technique, such as CMP, is performed to remove excess conductive material and ensure a smooth, flat surface of the substrate 111. The planarization helps eliminate any topographical variations and ensures uniformity across the semiconductor structure.

The method 200 continues with operation 202 and operation 203. Referring to FIG. 2, operation 202 includes forming a barrier layer on the substrate 111, and operation 203 includes forming a conductive layer on the barrier layer. In some embodiments, operation 202 and operation 203 of the method 200 are similar to operation 102 of the method 100.

Referring to FIG. 3, in some embodiments, a bit line stack 120 is formed on the substrate 111. The bit line stack 120 is configured to form the bit lines (not shown) after further patterning. In some embodiments, the barrier layer 121 of the bit line stack 120 is formed on the substrate 111, and the conductive layer 123 of the bit line stack 120 is formed on the barrier layer 121. In some embodiments, the barrier layer 121 is disposed on and in contact with the plurality of isolation structures 114 and the plurality of contacts 116, and the conductive layer 123 is disposed on and in contact with the barrier layer 121. In some embodiments, the bit line stack 120 is electrically connected to the contacts 116 and electrically isolated from the isolation structures 114 of the substrate 111.

In some embodiments, the barrier layer 121 includes Ti, Ta, TiN, TaN, Mn₃N₂ or a combination thereof. In some embodiments, the barrier layer 121 includes TiN. In some embodiments, the conductive layer 123 includes metal, such as W, Cu, Ru, Ir, Ni, Os, Rh, Al, Mo, Co, an alloy thereof, or a combination thereof. In some embodiments, the conductive layer 123 includes W.

In some embodiments, each of the barrier layer 121 and the conductive layer 123 may be formed, for example, by any acceptable deposition process, such as spin coating, CVD, ALD, PVD, laminating, the like, or a combination thereof.

The method 200 continues with operation 204. Referring to FIG. 2, operation 204 includes forming a nitride-containing layer on the conductive layer 123. In some embodiments, operation 204 of the method 200 is similar to operation 103 of the method 100.

In some embodiments, the nitride-containing layer 125 is formed on the bit line stack 120. In some embodiments, the nitride-containing layer 125 is in contact with the conductive layer 123. In some embodiments, the nitride-containing layer 125 includes silicon nitride (Si₃N₄), silicon oxynitride (N₂OSi₂), silicon nitride oxide (N₂OSi₂), or a combination thereof. In some embodiments, the nitride-containing layer 125 may be formed, for example, by any acceptable deposition process, such as spin coating, CVD, ALD, PVD, laminating, the like, or a combination thereof.

In some embodiments, a thickness T125 of the nitride-containing layer 125 is greater than a thickness T120 of the bit line stack 120.

The method 200 continues with operation 205. Referring to FIG. 2, operation 205 includes forming a hard mask layer on the nitride-containing layer 125, wherein a rate of etching the hard mask layer by an etchant is greater than a rate of etching the nitride-containing layer 125 by the etchant. In some embodiments, operation 205 of the method 200 is similar to operation 104 of the method 100.

In some embodiments, referring to FIG. 3, the hard mask layer 131 is formed on the nitride-containing layer 125. In some embodiments, a first dielectric constant of the nitride-containing layer 125 is different from a second dielectric constant of the hard mask layer 131, thereby providing an etch selectivity relative to the nitride-containing layer 125. In some embodiments, the first dielectric constant is less than the second dielectric constant.

In some embodiments, the hard mask layer 131 includes metal oxide and is free of carbon and nitride, and the rate of etching the hard mask layer 131 by the etchant is greater than the rate of etching the nitride-containing layer 125 by the etchant. In some embodiments, the hard mask layer 131 has a high etching selectivity relative to the nitride-containing layer 125. In some embodiments, the hard mask layer 131 includes ZrO₂, HfO₂, HSO, La₂O₃, LaAlO₃, ZrSiO₄, or a combination thereof. In some embodiments, the hard mask layer 131 includes ZrO₂, HfO₂, or a combination thereof. In some embodiments, the hard mask layer 131 may be formed, for example, by any acceptable deposition process, such as spin coating, CVD, ALD, PVD, laminating, the like, or a combination thereof.

In some embodiments, the thickness T125 of the nitride-containing layer 125 is greater than a thickness T131 of the hard mask layer 131. In some embodiments, the thickness T120 of the bit line stack 120 is greater than the thickness T131 of the hard mask layer 131. In some embodiments, the thickness T131 of the hard mask layer 131 is between 10Å and 40Å.

The method 200 continues with operation 206. Referring to FIG. 2, operation 206 includes forming a carbon-containing layer on the hard mask layer 131. In some embodiments, operation 206 of the method 200 is similar to operation 105 of the method 100.

In some embodiments, referring to FIG. 3, the carbon-containing layer 133 is formed on the hard mask layer 131. In some embodiments, the nitride-containing layer 125, the hard mask layer 131 and the carbon-containing layer 133 are disposed in sequence over the bit line stack 120. In some embodiments, the hard mask layer 131 is disposed between the carbon-containing layer 133 and the nitride-containing layer 125. In some embodiments, a third dielectric constant of the carbon-containing layer 133 is different from the second dielectric constant of the hard mask layer 131, thereby providing etch selectivity relative to the hard mask layer 131. In some embodiments, the third dielectric constant is less than the second dielectric constant.

In some embodiments, the carbon-containing layer 133 serves as a protective layer used to define and transfer patterns onto the underlying hard mask layer 131, and the hard mask layer 131 and the nitride-containing layer 125 are protective layers used to define and transfer patterns onto the underlying bit line stack 120 during various subsequent operations of the method 200. In some embodiments, the carbon-containing layer 133, the hard mask layer 131 and the nitride-containing layer 125 serve as a mask, providing resistance to etching chemicals, and help to ensure precise pattern transfer to and alignment with the underlying layers.

In some embodiments, the carbon-containing layer 133 may be a carbon-rich layer, while the hard mask layer 131 may be substantially free of carbon. In some embodiments, the carbon-containing layer 133 may be formed, for example, by any acceptable deposition process, such as spin coating, CVD, ALD, PVD, laminating, the like, or a combination thereof.

In some embodiments, a thickness T133 of the carbon-containing layer 133 is less than the thickness T125 of the nitride-containing layer 125. In some embodiments, the thickness T125 of the nitride-containing layer 125 is greater than two times the thickness T133 of the carbon-containing layer 133. In some embodiments, the thickness T125 of the nitride-containing layer 125 is greater than four times the thickness T133 of the carbon-containing layer 133. In some embodiments, the thickness T131 of the hard mask layer 131 is less than the thickness T133 of the carbon-containing layer 133. In some embodiments, the thickness T133 of the carbon-containing layer 133 is between 20nm and 50nm. In some embodiments, the thickness T133 of the carbon-containing layer 133 is between 30nm and 40nm.

In some embodiments, referring to FIG. 3, the method 200 further includes forming an anti-reflection coating layer 135 over the carbon-containing layer 133. In some embodiments, the anti-reflection coating layer 135 serves as a protective layer used to define and transfer patterns onto the underlying carbon-containing layer 133. In some embodiments, the formation of the anti-reflection coating layer 135 includes forming a first mask layer 137 including oxide over the carbon-containing layer 133 and forming a second mask layer 139 including silicon over the first mask layer 137. In some embodiments, the first mask layer 137 is an O-rich layer and the second mask layer 139 is a Si-rich layer. In some embodiments, each of the first mask layer 137 and second mask layer 139 may be formed, for example, by any acceptable deposition process, such as spin coating, CVD, ALD, PVD, laminating, the like, or a combination thereof.

In some embodiments, referring to FIG. 3, the method 200 further includes patterning the second mask layer 139 to expose portions 137p of the first mask layer 137. In some embodiments, portions of the second mask layer 139 are removed by an etching operation to expose the portions 137p of the first mask layer 137. The etching operation includes a plasma etch technique, a wet chemical etch technique, and/or another type of etch technique.

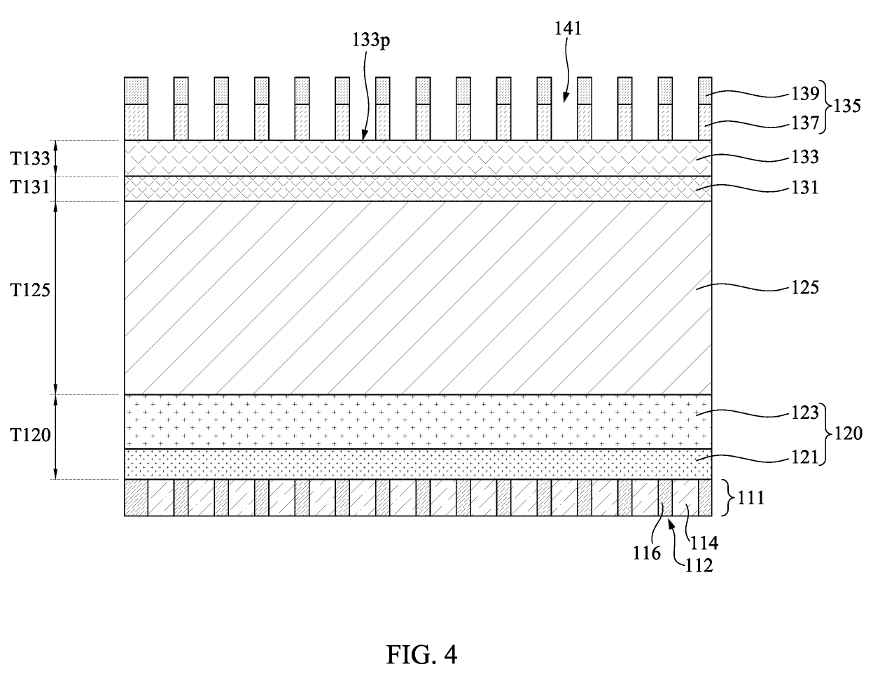

In some embodiments, referring to FIG. 4, the method 200 further includes patterning the first mask layer 137 to expose portions 133p of the carbon-containing layer 133. In some embodiments, the first mask layer 137 is etched to form a patterned first mask layer 137. In some embodiments, the first mask layer 137 is etched using the patterned second mask layer 139 as an etching mask, so that a pattern of the patterned second mask layer 139 is transferred to the first mask layer 137 to create the patterned first mask layer 137. The patterned first mask layer 137 has openings 141 which are formed in the portions 137p (as shown in FIG. 3). In some embodiments, the second mask layer 139 is consumed during the patterning of the first mask layer 137.

In some embodiments, the portions 137p (as shown in FIG. 3) of the first mask layer 137 exposed through the second mask layer 139 are removed by an etching operation to expose the portions 133p of the carbon-containing layer 133. The etching operation includes a plasma etch technique, a wet chemical etch technique, and/or another type of etch technique.

The method 200 continues with operation 207. Referring to FIG. 2, operation 207 includes patterning the carbon-containing layer 133 and the hard mask layer 131 to form a hard mask having an opening that exposes a portion of the nitride-containing layer. In some embodiments, operation 207 of the method 200 is similar to operation 106 and operation 107 of the method 100.

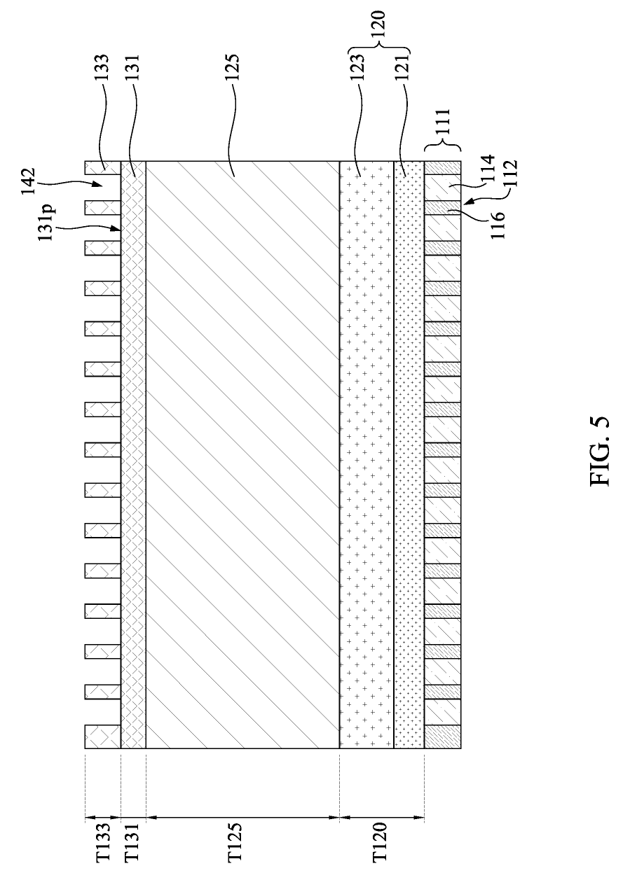

In some embodiments, referring to FIG. 5, operation 207 includes patterning the carbon-containing layer 133. In some embodiments, the anti-reflection coating layer 135 serves as an etching mask to pattern the carbon-containing layer 133, such that the patterned carbon-containing layer 133 exposes portions 131p of the hard mask layer 131. In some embodiments, the pattern of the anti-reflection coating layer 135 is transferred to the carbon-containing layer 133 to create the patterned carbon-containing layer 133. The patterned carbon-containing layer 133 has openings 142 which are extended from the openings 141 (as shown in FIG. 4).

In some embodiments, the portions 133p (as shown in FIG. 4) of the carbon-containing layer 133 exposed by the anti-reflection coating layer 135 are removed by an etching operation to expose the portions 131p of the hard mask layer 131. The etching operation or the patterning operation includes a plasma etching process, a wet etching process, a dry etching process, and/or another type of etch technique. In some embodiments, the portions 133p of the carbon-containing layer 133 are removed by a dry etching process. In some embodiments, a dry etchant, such as hydrogen (H₂) or nitrogen (N₂), may be used in the dry etching process. In some embodiments, the portions 133p of the carbon-containing layer 133 are removed by a wet etching process. An etchant used in the wet etching process may include sulfuric acid (H₂SO₄), hydrogen peroxide (H₂O₂), hydrofluoric acid (HF), ammonium hydroxide (NH₄OH), or a combination thereof. In some embodiments, after the carbon-containing layer 133 is patterned, the anti-reflection coating layer 135 is removed.

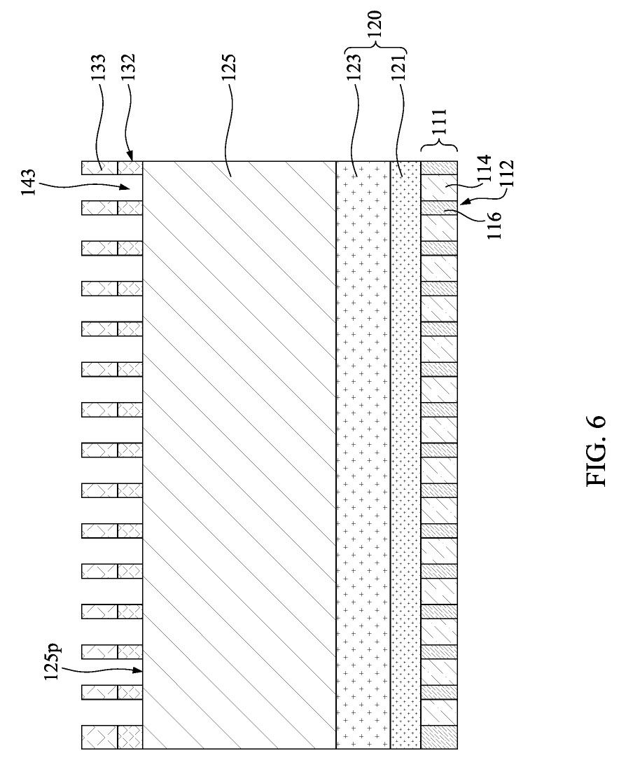

In some embodiments, referring to FIG. 6, operation 207 includes patterning the hard mask layer 131 layer to form a hard mask 132 having an opening 143 that exposes the nitride-containing layer 125. In some embodiments, the hard mask layer 131 is etched to form the hard mask 132 having a pattern. In some embodiments, the hard mask layer 131 is etched using the patterned carbon-containing layer 133 as an etching mask, so that the pattern of the carbon-containing layer 133 is transferred to the hard mask layer 131 to form the hard mask 132 having the pattern. The hard mask 132 has the openings 143 which have been extended from the openings 142 (as shown in FIG. 5). In some embodiments, the patterned carbon-containing layer 133 is consumed during the patterning of the hard mask layer 131. In some embodiments, the anti-reflection coating layer 135 is also fully consumed during the patterning of the hard mask layer 131 if the anti-reflection coating layer 135 has not already been fully consumed.

In some embodiments, referring to FIG. 5, the carbon-containing layer 133 serves as an etching mask to pattern the hard mask layer 131, and, referring to FIG. 6, the patterned hard mask layer 131 exposes portions 125p of the nitride-containing layer 125. In some embodiments, the portions 131p (as shown in FIG. 5) of the hard mask layer 131 exposed by the patterned carbon-containing layer 133 are removed by an etching operation to expose the portions 125p of the nitride-containing layer 125. The etching operation or the patterning operation includes a plasma etching process, a wet etching process, a dry etching process, and/or another type of etch technique. In some embodiments, the etching operation for patterning the hard mask layer 131 to form the hard mask 132 includes a wet etching process. An etchant used in the wet etching process may include sulfuric acid (H₂SO₄), hydrogen peroxide (H₂O₂), hydrofluoric acid (HF), ammonium hydroxide (NH₄OH), or a combination thereof.

In some embodiments, an etching rate of the etching of the hard mask layer 131 is greater than an etching rate of the etching of the nitride-containing layer 125. In some embodiments, the etching rate of the etching of the nitride-containing layer 125 is substantially equal to zero.

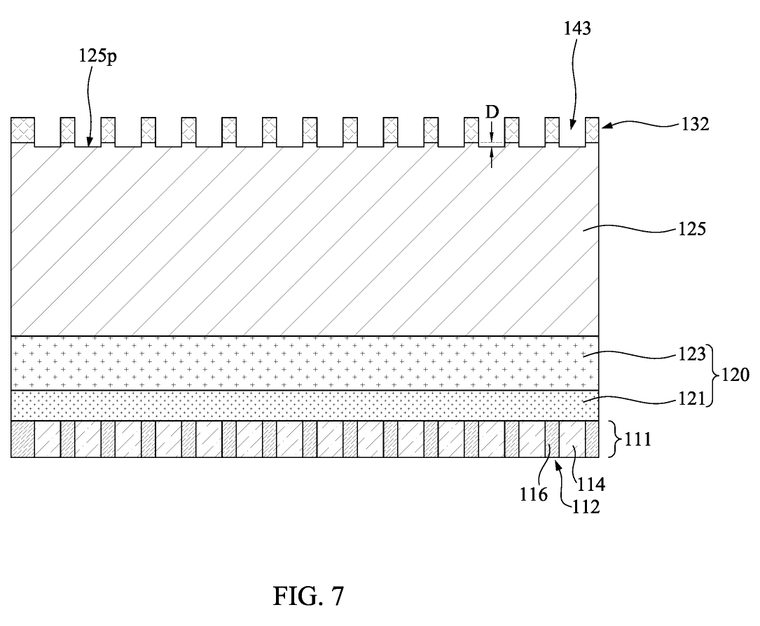

In some embodiments, referring to FIG. 7, the etching rate of the etching of the nitride-containing layer 125 is greater than zero. In some embodiments, a breakthrough (BT) etch process is performed to form the hard mask 132. The hard mask 132 is etched using the patterned carbon-containing layer 133 as the etching mask, so that the pattern of the carbon-containing layer 133 is transferred to the hard mask 132 and a top portion of the nitride-containing layer 125. The patterned hard mask 132 has openings 143 which have been extended from the openings 142 (as shown in FIG. 5). The BT etch process can include any suitable etch process, such as a wet etch process or a dry etch process. In some embodiments, following the BT etch process, a recess in the openings 143 is extended into the nitride-containing layer 125, wherein the recess may have a depth D between about 10Å and about 3nm, such as about 10Å to about 1nm.

The method 200 continues with operation 208. Referring to FIG. 2, operation 208 includes removing the carbon-containing layer 133 after the formation of the hard mask 132. In some embodiments, operation 208 of the method 200 is similar to operation 108 of the method 100.

In some embodiments, referring to FIG. 7, after the hard mask layer 131 is patterned and the hard mask 132 is formed, the patterned carbon-containing layer 133 is removed or stripped. In some embodiments, during the formation of the hard mask 132, the patterned carbon-containing layer 133 is fully consumed. In some embodiments, if the patterned carbon-containing layer 133 remains disposed on the hard mask 132, undesirable carbon by-product may be generated in subsequent processes and may be in contact with the nitride-containing layer 125 and the bit line stack 120. In some embodiments, if the patterned carbon-containing layer 133 remains disposed on the hard mask 132 after the hard mask 132 is formed, the removal of the patterned carbon-containing layer 133 in subsequent processes may cause oxidation of the conductive layer 123, which can affect electrical properties of the formed semiconductor structure.

The method 200 continues with operation 209. Referring to FIG. 2, operation 209 includes using the hard mask 132 to pattern the nitride-containing layer 125, the conductive layer 123 and the barrier layer 121, thereby forming a bit line 129 on the contact 116 and a nitride-containing element 126 on the bit line 129. In some embodiments, operation 209 of the method 200 is similar to operation 109 of the method 100. In some embodiments, a semiconductor structure 300 is formed. In some embodiments, the semiconductor structure 300 is fabricated by the method 100 or the method 200.

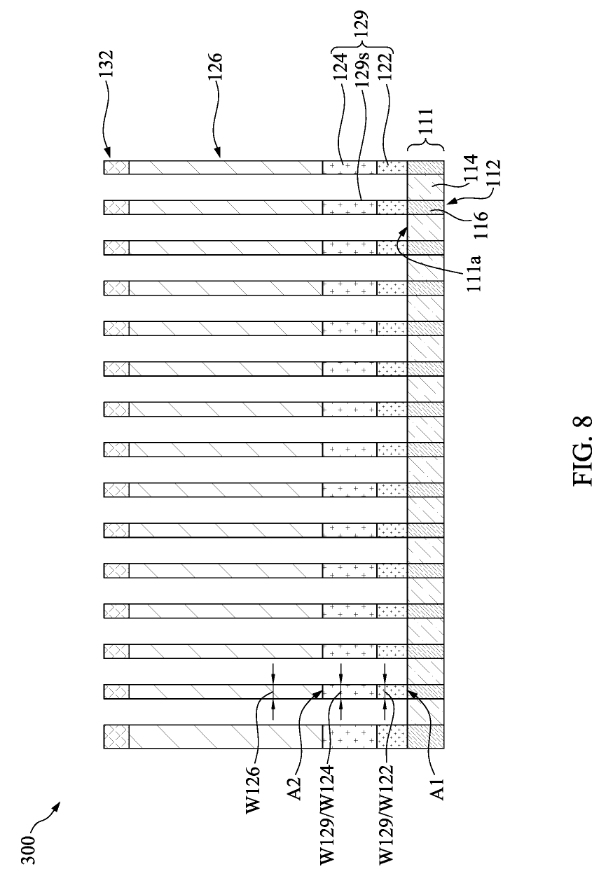

Referring to FIGS. 7 and 8, in some embodiments, after the patterned carbon-containing layer 133 (as shown in FIG. 6) is removed, the hard mask 132 is used to pattern the nitride-containing layer 125, the conductive layer 123 and the barrier layer 121 to form a plurality of the bit lines 129 and a plurality of the nitride-containing elements 126 disposed on the corresponding bit lines 129.

In some embodiments, the hard mask 132 serves as an etching mask to pattern the nitride-containing layer 125 and the bit line stack 120, thus forming the plurality of bit lines 129 and the plurality of nitride-containing elements 126 exposing the isolation structure 114 of the substrate 111. In some embodiments, the pattern of the hard mask 132 is transferred to the nitride-containing layer 125 and the bit line stack 120 to form the plurality of bit lines 129 and the plurality of nitride-containing elements 126 disposed thereon. In some embodiments, the bit line 129 is patterned and formed after the removal of the patterned carbon-containing layer 133, and the hard mask 132 alone serves as the etching mask to pattern the nitride-containing layer 125 and the bit line stack 120, so that residue of the patterned carbon-containing layer 133 may not have a chance to come in contact with the bit lines 129 or fall between the adjacent bit lines 129. In some embodiments, the bit lines 129 and the substrate 111 are free of the residue of the carbon-containing layer 133 disposed thereon.

In some embodiments, the portions 125p of the nitride-containing layer 125 exposed through the hard mask 132 are removed by an etching operation, thereby exposing the isolation structures 114 of the substrate 111. The etching operation includes a plasma etching process, a wet etching process, a dry etching process, and/or another type of etch technique.

In some embodiments, referring to FIG. 8, the patterning of the bit line stack 120 to form the bit line 129 includes forming a plurality of first portions 122 electrically and physically connected to the contact 116, and forming a plurality of second portions 124 disposed over the first portion 122. In some embodiments, one of the first portions 122 and its corresponding second portion 124 are in contact with each other. In some embodiments, each of the bit lines 129 includes one of the first portions 122 and the corresponding second portion 124, and the second portion 124 is formed prior to the forming of the corresponding first portion 122. In some embodiments, each of the bit lines 129 is disposed under its corresponding nitride-containing element 126, and the corresponding second portion 124 of the bit line 129 is disposed between the corresponding first portion 122 of the bit line 129 and the corresponding nitride-containing element 126.

In some embodiments, a first width W122 of the first portion 122 is substantially equal to a second width W124 of the second portion 124. In some embodiments, a width W129 of the bit line 129 is between 5nm and 15nm. In some embodiments, the nitride-containing element 126 has a third width W126, wherein the third width W126 is between 5nm and 15nm. In some embodiments, the width W129 of the bit line 129 is substantially equal to the third width W126 of the nitride-containing element 126. In some embodiments, the first width W122 of the first portion 122 is substantially equal to the third width W126 of the nitride-containing element 126, and the second width W124 of the second portion 124 is substantially equal to the third width W126 of the nitride-containing element 126.

In some embodiments, the first portion 122 has a first cross-sectional area A1 and the second portion 124 has a second cross-sectional area A2, wherein the first cross-sectional area A1 is substantially equal to the second cross-sectional area A2.

In some embodiments, the first portion 122 and the second portion 124 include different materials. In some embodiments, the first portion 122 includes TiN. In some embodiments, the second portion includes W.

In some embodiments, the substrate 111 has a first surface 111a, and the bit line 129 is disposed on the first surface 111a. In some embodiments, a sidewall 129s of the bit line 129 is substantially perpendicular to the first surface 111a of the substrate 111.

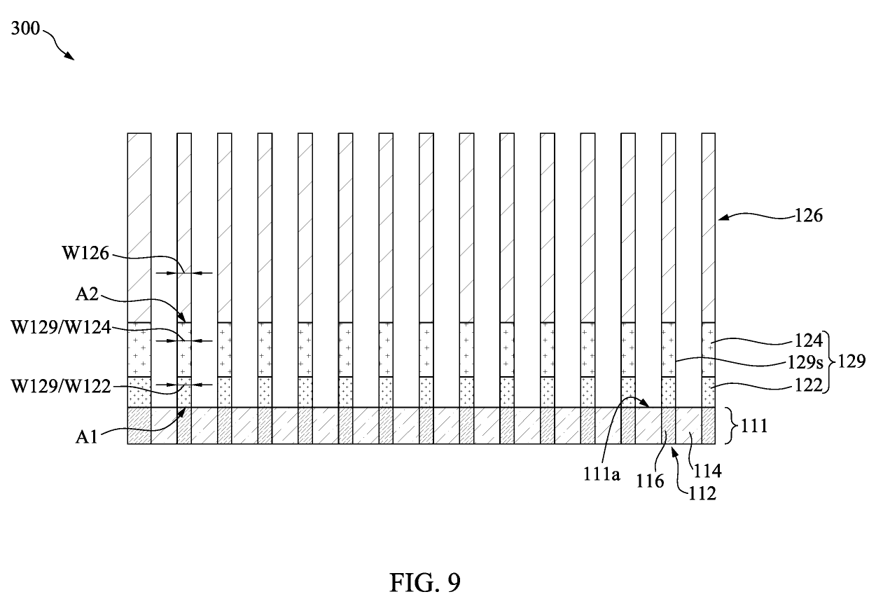

In some embodiments, referring to FIG. 9, the method 200 further includes removing the hard mask 132 from the semiconductor structure 300 after the formation of the bit line 129. In some embodiments, no undercut is formed on the bit line 129 and the nitride-containing element 126. In some embodiments, the hard mask 132 is removed by stripping, an etching operation or a patterning operation including a plasma etching process, a wet etching process, a dry etching process, and/or another type of etch technique. In some embodiments, the hard mask 132 is removed by a dry etching process. In some embodiments, a CMP process is avoided during the removal of the hard mask 132, so that tiny particles often generated by processes such as a CMP process are less likely to fall into openings between the bit lines 129, thereby avoiding damage to the semiconductor structure 300 during subsequent processes.

In conclusion, due to removal of a carbon-containing layer prior to formation of a bit line, the bit line formed by the method of the present disclosure is free of residue from the carbon-containing layer. Moreover, a nitride-containing layer and a bit line stack are patterned with a hard mask having metal oxide to form the bit line, wherein an etch rate of an etching of the hard mask layer by an etchant is greater than an etch rate of an etching of the nitride-containing layer by the etchant. As a result, a semiconductor structure of the present disclosure includes the bit line having a first portion and second portion disposed over the first portion, wherein a first width of the first portion is substantially equal to a second width of the second portion, and favorable electrical performance and reliability of the semiconductor structure are ensured.

One aspect of the present disclosure provides a method of manufacturing a semiconductor structure. The method includes providing a substrate having an active region, wherein the active region includes an isolation structure and a contact adjacent to the isolation structure; forming a bit line stack on the substrate; forming a nitride-containing layer on the bit line stack; and forming a hard mask layer on the nitride-containing layer, wherein the hard mask layer includes metal oxide and an etching rate of etching the hard mask layer by an etchant is greater than an etching rate of etching the nitride-containing layer by the etchant. The method further includes forming a carbon-containing layer on the hard mask layer; patterning the carbon-containing layer to expose a portion of the hard mask layer; removing the portion of the hard mask layer to form a hard mask having an opening, thereby exposing a portion of the nitride-containing layer; removing the carbon-containing layer after the formation of the hard mask; and using the hard mask to pattern the nitride-containing layer and the bit line stack, thereby forming a bit line on the contact and a nitride-containing element on the bit line.

Another aspect of the present disclosure provides a method of manufacturing a semiconductor structure. The method includes providing a substrate having an active region, wherein the active region includes a contact; forming a barrier layer on the substrate; forming a conductive layer on the barrier layer; forming a nitride-containing layer on the conductive layer; forming a hard mask layer on the nitride-containing layer, wherein an etching rate of etching the hard mask layer by an etchant is greater than an etching rate of etching the nitride-containing layer by the etchant; and forming a carbon-containing layer on the hard mask layer. The method further includes patterning the carbon-containing layer and the hard mask layer to form a hard mask having an opening, thereby exposing the nitride-containing layer; removing the carbon-containing layer after the formation of the hard mask; and using the hard mask to pattern the nitride-containing layer, the conductive layer and the barrier layer, thereby forming a bit line and a nitride-containing element on the bit line, wherein the nitride-containing layer is patterned after the removal of the carbon-containing layer.

Another aspect of the present disclosure provides a semiconductor structure. The semiconductor structure includes a substrate comprising an active area; a contact disposed in the active area; and a bit line electrically connected to the contact, wherein the bit line includes a first portion and a second portion disposed over the first portion, wherein a first width of the first portion is substantially equal to a second width of the second portion.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods and steps.

What is claimed is:

1. A method of manufacturing a semiconductor structure, comprising:
providing a substrate having an active region, wherein the active region includes a contact;
forming a barrier layer on the substrate;
forming a conductive layer on the barrier layer;
forming a nitride-containing layer on the conductive layer;
forming a hard mask layer on the nitride-containing layer, wherein a rate of etching the hard mask layer by an etchant is greater than a rate of etching the nitride-containing layer by the etchant;
forming a carbon-containing layer on the hard mask layer;
patterning the carbon-containing layer and the hard mask layer to form a hard mask having an opening, thereby exposing a portion of the nitride-containing layer;
removing the carbon-containing layer after the formation of the hard mask; and
using the hard mask to pattern the nitride-containing layer, the conductive layer and the barrier layer, thereby forming a bit line on the contact and a nitride-containing element on the bit line,
wherein the nitride-containing layer is patterned after the removal of the carbon-containing layer.

2. The method of claim 1, wherein the hard mask layer includes ZrO₂ HfO₂ HSO, La₂O₃ LaAlO₃ ZrSiO₄ or a combination thereof.

3. The method of claim 1, further comprising:
removing the hard mask after the formation of the bit line.

4. The method of claim 1, further comprising:
forming an anti-reflection coating layer over the carbon-containing layer.

5. The method of claim 4, wherein the formation of the anti-reflection coating layer includes:
forming a first mask layer including oxide over the carbon-containing layer;
forming a second mask layer including silicon over the first mask layer;
patterning the second mask layer to expose a portion of the first mask layer; and
patterning the first mask layer to expose a portion of the carbon-containing layer before the formation of the opening.

6. The method of claim 1, wherein a thickness of the carbon-containing layer is between 20nm and 50nm.

7. The method of claim 1, wherein a thickness of the hard mask layer is between 10Å and 40Å.

8. The method of claim 1, wherein a width of the bit line is between 5nm and 15nm.

9. The method of claim 1, wherein the bit line includes a first portion and a second portion disposed over the first portion, and a first width of the first portion is substantially equal to a second width of the second portion.

10. The method of claim 1, wherein the barrier layer includes TiN and the conductive layer includes W.

11. The method of claim 1, wherein the contact includes polysilicon.
